(19) United States
(12) Patent Application Publication
(10) Pub. No.: US 2022/0164141 A1
(43) Pub. Date: May 26, 2022

(54) Memory Controller Utilizing Sets of Access Settings Corresponding to Memory Dies, and Control Method thereof

(71) Applicant: Realtek Semiconductor Corp., HsinChu (TW)

(72) Inventors: WU HONG, Suzhou City (CN); DAOFU WANG, Suzhou City (CN); YONGPENG JING, Suzhou City (CN)

(21) Appl. No.: 17/194,298

(22) Filed: Mar. 7, 2021

(30) Foreign Application Priority Data
Nov. 24, 2020 (CN) 202011328277.9

(51) Int. Cl. G06F 3/06

(52) U.S. Cl. CPC G06F 3/0659; G06F 3/0604; G06F 3/0679

(57) ABSTRACT

A memory controller is used to access a plurality of NAND flash dies. The memory controller includes an internal memory, an output selection circuit, a control circuit and a data access circuit. The internal memory is configured to store plural sets of access settings corresponding to the NAND flash dies. The output selection circuit is coupled to the internal memory and is configured to select a set of access settings corresponding to a NAND flash die. The control circuit is coupled to the output selection circuit and is configured to generate an output selection signal when accessing the NAND flash die. The data access circuit is coupled to the output selection circuit and is configured to access the NAND flash die according to the set of access settings corresponding thereto.

### CROSS REFERENCE TO RELATED APPLICATION

This non-provisional application claims priority of China patent application No. 202011328277.9, filed on 24 Nov. 2020, included herein by reference in its entirety.

### BACKGROUND OF THE INVENTION

### 1. Field of the Invention

The invention relates to electronic circuits, and in particular, to a memory controller and a control method thereof.

### 2. Description of the Prior Art

Non-volatile memories are widely used in personal computers, telecommunications, consumer electronics and other fields. Typically, the non-volatile memories employ a NAND memory as the storage medium. The NAND memory has the properties of relatively long response time and high throughput. As technology advances, the NAND memory has evolved from a two-dimensional (2D) structure to a three-dimensional (3D) structure, and increasing numbers of 3D layers are added to such structure. The development of NAND memory cell has progressed from triple-level cells (TLC), to quad-level cells (QLC), and then to multi-level cells (x-level cell, XLC), leading to a significant growth in the storage capability of a single NAND memory die, while complicating internal operations and accumulating performance variations among a group of NAND memory cells, and that degrades the performance and increases the power consumption of the NAND memory.

### SUMMARY OF THE INVENTION

According to one embodiment of the invention, a memory controller capable of accessing a plurality of NAND memory dies includes a first internal memory, an output selection circuit, a control circuit and a data access circuit. The first internal memory is configured to store a plurality of sets of access settings corresponding to the plurality of NAND memory dies. The output selection circuit is coupled to the first internal memory and is configured to select a set of access settings corresponding to a NAND memory die according to an output selection signal. The control circuit is coupled to the output selection circuit and is configured to generate the output selection signal when accessing the NAND memory die. The data access circuit is coupled to the output selection circuit and is configured to access the NAND memory die according to the set of access settings.

According to another embodiment of the invention, a memory controller is coupled to a plurality of NAND memory dies. The memory controller includes a first internal memory, an output selection circuit, a control circuit and a data access circuit. A method of controlling the memory controller includes following steps: the first internal memory storing a plurality of sets of access settings corresponding to the plurality of NAND memory dies; when accessing a NAND memory die, the control circuit generating an output selection signal; the output selection circuit selecting a set of access settings corresponding to the NAND memory die according to the output selection signal; and the data access circuit accessing the NAND memory die according to the set of access settings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a memory device according to an embodiment of the invention.

FIG. 2 is a flowchart of a method of controlling the memory device in FIG. 1.

FIG. 3 is a flowchart of another method of controlling the memory device in FIG. 1.

FIG. 4 is a flowchart of another method of controlling the memory device in FIG. 1.

FIG. 5 is a flowchart of another method of controlling the memory device in FIG. 1.

### DETAILED DESCRIPTION

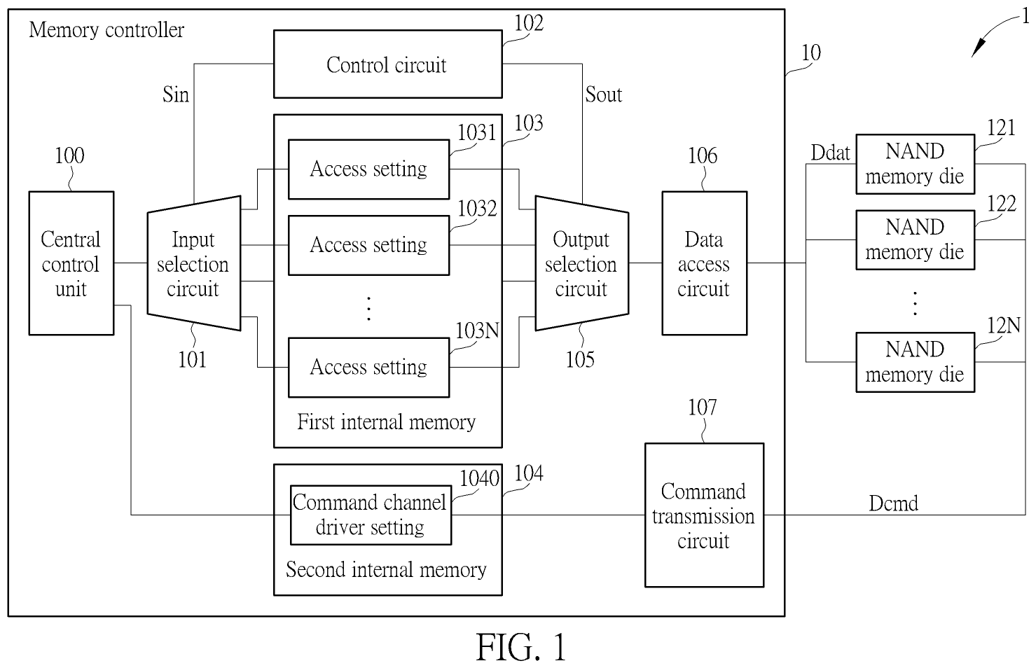

FIG. 1 is a block diagram of a memory device 1 according to an embodiment of the invention. The memory device 1 may be a solid state drive (SSD), an embedded multimedia memory card (EMMC) or a NAND flash memory device compliant with the open NAND flash interface (ONFI) standard and/or the toggle mode standard. The memory device 1 may include a memory controller 10 and NAND memory dies 121˜12N, where N may be, but is not limited to, an integer greater than 2 and may represent the next digit after the number 12. The memory controller 10 is coupled to the NAND memory dies 121-12N to control data access operations of the NAND memory dies 121-12N, including data writing operations and data reading operations. The NAND memory dies 121-12N may perform a pipeline communication with the memory controller 10 to increase the data transfer rate. As the number N of the NAND memory dies 121˜12N grows, the performances of the NAND memory dies 121˜12N may vary considerably, and the finite size of the circuit board may introduce a wiring mismatch between the NAND memory dies 121˜12N. Therefore, the memory controller 10 may configure a plurality of sets of access settings for data accesses of the NAND memory dies 121˜12N according to respective driving capabilities and anti-interference capability. In a factory test, the memory device 1 may undergo various tests with respect to wiring variations and performance variations of NAND memory dies to acquire sets of corresponding access settings. When in use, the memory device 1 may perform data access according to a set of corresponding access settings for each NAND memory die, so as to enhance the performance of the memory device 1 and reduce the power consumption of the memory device 1.

The memory controller 10 includes a central control unit 100, an input selection circuit 101, a control circuit 102, a first internal memory 103, a second internal memory 104, an output selection circuit 105, a data access circuit 106, and a command transmission circuit 107. The central control unit 100 is coupled to the input selection circuit 101 and the second internal memory 104. The control circuit 102 is coupled to the input selection circuit 101 and the output selection circuit 105. The first internal memory 103 is coupled to the input selection circuit 101 and the output selection circuit 105. The output selection circuit 105 is coupled to the data access circuit 106. The second internal memory 104 is coupled to the command transmission circuit 107. The data access circuit 106 and the command transmission circuit 107 are coupled to the NAND memory dies 121-12N.

The first internal memory 103 may store a plurality of sets of access settings 1031˜103N corresponding to the NAND memory dies 121˜12N, where N represents the next digit after the number 103. For example, a set of access settings 1031 may correspond to the NAND memory die 121, and another set of access settings 1032 may correspond to the NAND memory die 122. The first internal memory 103 may be a non-volatile memory. Each set of access settings includes an output driver strength (ODS) and an on-die termination (ODT) corresponding to a NAND memory die. The output driver strengths may be represented by driver resistances in Table 1:

TABLE 1

| Supply voltage (Volts) | Driver resistance (ohms) |
|---|---|
| 3.3 | 18 |
| | 25 |
| | 35 |
| | 50 |
| 1.8 | 18 |
| | 25 |
| | 35 |
| | 50 |
| 1.8/1.2 | 25 |
| | 35 |
| | 50 |

The data access circuit 106 may include an input/output driver, and the number of the driver strength settings may be associated with the supply voltage of the input/output driver. For example, when the supply voltage of the input/output driver is 1.8V, the supported driver strength settings of the data access circuit 106 may be 2.0 times, 1.4 times, 1.0 time or 0.7 times to provide 18 ohms, 25 ohms, 35 ohms and 50 ohms of driver resistances, respectively. A smaller driver resistance may correspond to a larger driver strength setting. The driver strength resistances shown in Table 1 only serve as an example but not a limitation to the present invention.

The on-die termination settings corresponding to the on-die terminations may be represented by on-die termination resistances shown in Table 2:

TABLE 2

| On-die termination setting | On-die termination resistance |
|---|---|
| (bits) | (ohms) |
| 0000001000 | 150 |
| 0000001100 | 100 |
| 0000010000 | 75 |
| 0000011000 | 50 |
| 0000101000 | 30 |

Table 2 shows that the 5 on-die termination settings may provide the on-die termination resistances of 150 ohms, 100 ohms, 75 ohms, 50 ohms and 30 ohms at the output selection circuit 105, respectively. A smaller on-die termination resistance may provide the data access circuit 106 with stronger anti-interference capability during data reception. However, an on-die termination resistance that is too small may affect the feature of eye opening in the eye diagram, resulting in a signal quality reduction. When the transmission quality between the memory controller 10 and the NAND memory dies is good and the noise interference is low, the data access circuit 106 may even employ no on-die termination resistance and receive the data Ddat directly from the NAND memory die. The on-die termination settings shown in Table 2 serve as an example but not a limitation to the present invention.

In one example, the number of NAND memory dies may be four (i.e., N=4), and the plurality of sets of NAND memory dies 121-124 corresponding to the access settings 1031-1034 are shown as in Table 3.

TABLE 3

| | NAND | NAND | NAND | NAND |
|---|---|---|---|---|
| | memory | memory | memory | memory |
| | die 121 | die 122 | die 123 | die 124 |
| Driver | 25 | 35 | 35 | 35 |
| resistance | | | | |
| (ohms) | | | | |
| On-die | 100 | 150 | ∞ | 150 |
| termination | | | | |
| resistance | | | | |
| (ohms) | | | | |

Table 3 shows that the data access circuit 106 has a weak data transmission capability and a normal data reception capability with respect to the NAND memory die 121, and the access setting 1031 corresponding to the NAND memory die 121 may be configured to a low driver resistance (25 ohms) and a medium on-die termination resistance (100 ohms); the data access circuit 106 has a normal data transmission capability and a normal data reception capability with respect to the NAND memory dies 122 and 124, and the access settings 1032 and 1034 corresponding to the NAND memory dies 122 and 124 may be configured to a medium driver resistance (35 ohms) and a medium on-die termination resistance (150 ohms); the data access circuit 106 has a normal data transmission capability and a strong data reception capability with respect to the NAND memory die 123, and the access setting 1033 corresponding to the NAND memory die 123 may be configured to a medium driver resistance (35 ohms) and infinite on-die termination resistance (indicated as an infinity symbol in the figure).

When accessing a NAND memory die 12n, the control circuit 102 may generate an output selection signal Sout, where n is a positive integer between 1 and N. The output selection circuit 105 may select a set of access settings 103n of the NAND memory die 12n according to the output selection signal Sout. The output selection circuit 105 may be implemented by a multiplexer. The control circuit 102 may adopt multiple chip enable (CE) pins or a reduced chip enable pin to generate the output selection signal Sout. When adopting the multiple chip enable pins, N chip enable signals may correspond to the NAND memory dies 121˜12N. For example, the NAND memory dies 121˜12N may correspond to chip enable signals CE1˜CEN, respectively, N representing the next digit after CE. When accessing the NAND memory die 12n, the control circuit 102 may use the nth chip enable signal as the output selection signal Sout for the output selection circuit 105 to select the corresponding set of access settings 103n. When adopting the reduced chip enable pin, the control circuit 102 may use a logical unit number (referred to as an LUN) or a preset memory number (referred to as a volume) to generate the output selection signal Sout. In some embodiments, the memory controller 10 uses the LUN to generate the output selection signal Sout, and the N logical unit numbers may correspond to the NAND memory die 121-12N. For example, the NAND memory dies 121 to 12N may correspond to logical unit numbers LUN1 to LUNN, respectively, wherein N represents the next digit after LUN. When accessing the NAND memory die 12n, the control circuit 102 may employ a logical unit number LUNn corresponding to the NAND memory die 12n as the output selection signal Sout for that the output selection circuit 105 to select the set of access settings 103n. In alternative embodiments, the memory controller 10 adopts the preset volume to generate the output selection signal Sout, and N volumes may correspond to the NAND memory dies 121-12N. For example, the user may appoint volumes V1˜VN to the NAND memory dies 121˜12N after a boot,wherein N represents the next digit after V. When accessing the NAND memory die 12n, the control circuit 102 may use an preset volume Vn corresponding to the NAND memory die 12n as the output selection signal Sout for the output selection circuit 105 to select the set of access settings 103n.

The data access circuit 106 may access the NAND memory die 12n according to the set of access settings 103n. Specifically, the data access circuit 106 may transmit the data Ddat to the NAND memory die 12n according to the corresponding output driver strength (ODS), and receive the data Ddat from the NAND memory die 12n according to the corresponding on-die termination resistance.

When configuring the set of access settings 103n, the control circuit 102 may generate an input selection signal Sin, the central control unit 100 may output driver strength settings and/or on-die termination settings of an updated set of the settings, and the input selection circuit 101 may output the driver strength setting and/or the on-die termination setting of the set of access settings to the first internal memory 103 according to the input selection signal Sin from the control circuit 102, so as to update the set of accesses settings 103n corresponding to the NAND memory die 12n. The input selection circuit 101 may be implemented by a multiplexer. The input selection signal Sin may be generated using the multiple chip enable pins or the reduced chip enable pin. The multiple chip enable pins and the reduced chip enable pin have been explained in the preceding paragraphs, and explanation therefor will not be repeated here.

The second internal memory 104 may store a command channel driver setting 1040 of the NAND memory dies 121-12N. Since the command Dcmd is transmitted at a relatively low speed and has a low requirement for the output driver strength, the NAND memory dies 121-12N may share the same command channel driver setting 1040 for data transmission to reduce costs. The second internal memory 104 may be a non-volatile memory. The command transmission circuit 107 may transmit the command Dcmd to the NAND memory die 12n according to the command channel driver setting 1040. The command channel driver setting 1040 may be represented by a driver resistance in Table 1. While the command Dcmd is transmitted according to the same command channel driver setting 1040 in the present embodiment, those skilled in the art may also configure multiple corresponding command channel driver settings for the NAND memory dies 121-12N as needed, so as to enhance the transmission performance.

The memory device 1 sets a set of corresponding access settings for each NAND memory die to enhance the performance of the memory device 1 and reduce the power consumption of the memory device 1.

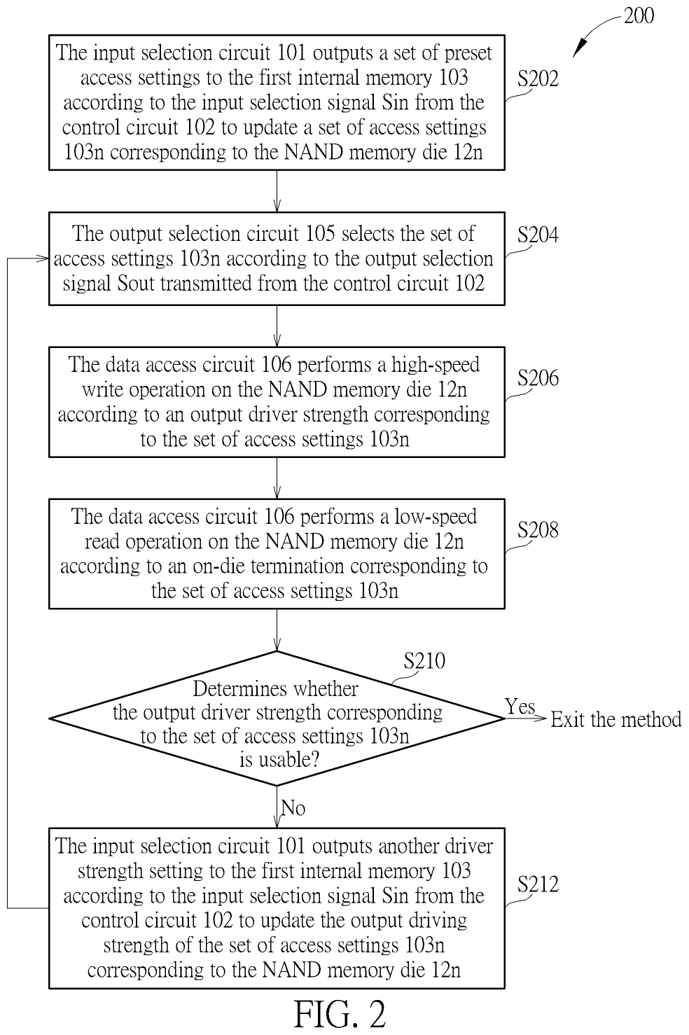

FIG. 2 is a flowchart of a method 200 of controlling the memory controller 10. The control method 200 includes steps S202-S212, sequentially performing tests on the NAND memory dies 121-12N to obtain the corresponding output driver strengths thereof in a factory test. Any reasonable step change or adjustment is within the scope of the disclosure. Steps S202-S212 are detailed as follows:

Step S202: The input selection circuit 101 outputs a set of preset access settings to the first internal memory 103 according to the input selection signal Sin from the control circuit 102 to update a set of access settings 103n corresponding to the NAND memory die 12n;

Step S204: The output selection circuit 105 selects the set of access settings 103n according to the output selection signal Sout transmitted from the control circuit 102;

Step S206: The data access circuit 106 performs a high-speed write operation on the NAND memory die 12n according to an output driver strength corresponding to the set of access settings 103n;

Step S208: The data access circuit 106 performs a low-speed read operation on the NAND memory die 12n according to an on-die termination corresponding to the set of access settings 103n;

Step S210: The central control unit 100 determines whether the output driver strength corresponding to the set of access settings 103n is usable? If so, exit the method 200; and if not, proceed to Step S212;

Step S212: The input selection circuit 101 outputs another driver strength setting to the first internal memory 103 according to the input selection signal Sin from the control circuit 102 to update the output driving strength of the set of access settings 103n corresponding to the NAND memory die 12n; proceed to Step S204.

In Step S202, the set of preset access settings may be obtained based on the experience, or may be the maximum driver resistance (e.g., 50 ohms) and the maximum on-die termination resistance (e.g., 150 ohms). In Step S204, the output selection circuit 105 selects the set of access settings 103n corresponding to the NAND memory die 12n. To obtain an enhanced output driver strength corresponding to the NAND memory die 12n, the data access circuit 106 writes predetermined data into the NAND memory die 12n at a high writing speed (Step S206), and then reads data from the NAND memory die 12n at a low reading speed (Step S208). In some embodiments, the high writing speed may be, but is not limited to, 1600 MHz, and the low reading speed may be, but is not limited to, 50 MHz. In Step S210, the central control unit 100 compares the read data to the predetermined data. If the read data matches the predetermined data, it is determined that the output driver strength corresponding to the NAND memory die 12n is usable (or say suitable), and the method 200 may be exited. If the red data fails to match the predetermined data, it is determined that the output driver strength corresponding to the NAND memory die 12n is unusable (or say unsuitable). In Step S212, since the corresponding output driver strength is unusable, the central control unit 100 outputs another driver strength setting to update the output driver strength corresponding to the set of access settings 103n. In some embodiments, another driver strength setting corresponds to another driver resistance less than the previous driver resistance.

The memory controller 10 executes the control method 200 on the NAND memory dies 121-12N in turn to obtain the output driver strengths corresponding to the plurality of sets of access settings 1031-103N. While in the embodiment, the method 200 may be exited upon obtaining the usable output driver strengths, in other embodiments, the memory controller 10 may execute the method 200 to iterate over all driver strength settings and determine all usable driver resistances, and update the maximum driver resistance among all the usable driver resistances as the output driver strength corresponding to the set of access settings 103n, so as to reduce power consumption while transmitting data to the NAND memory die 12n accurately.

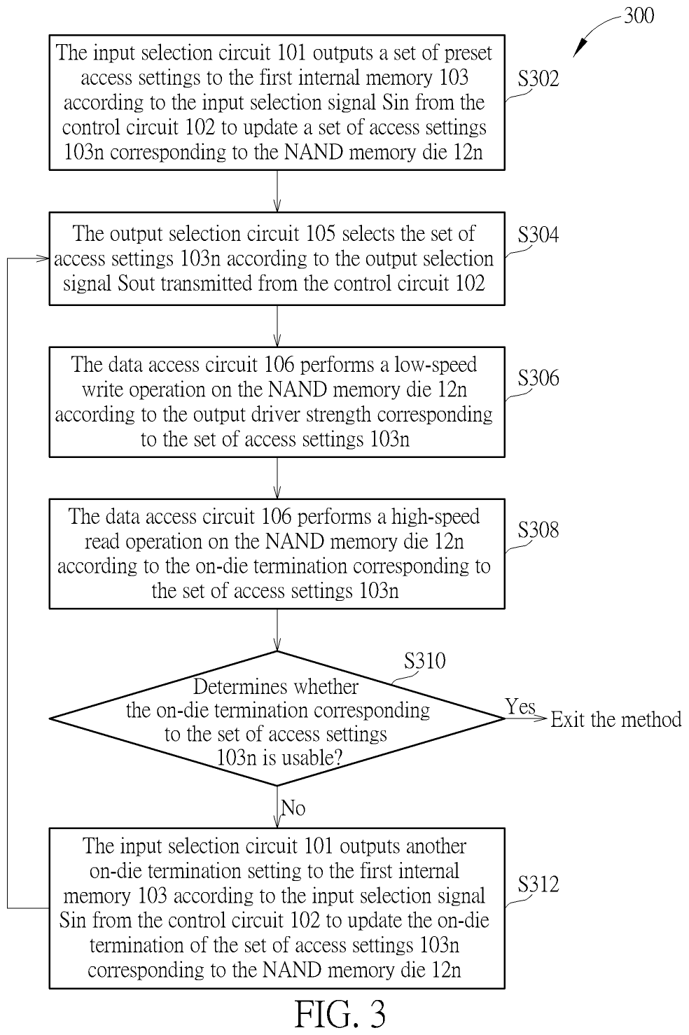

FIG. 3 is a flowchart of another method 300 of controlling the memory controller 10. The control method 300 includes steps S302-S312, sequentially performing tests on the NAND memory dies 121-12N to obtain their corresponding on-die terminations in a factory test. Any reasonable step change or adjustment is within the scope of the disclosure. Steps S302-S312 are detailed as follows:

Step S302: The input selection circuit 101 outputs a set of preset access settings to the first internal memory 103 according to the input selection signal Sin from the control circuit 102 to update a set of access settings 103n corresponding to the NAND memory die 12n;

Step S304: The output selection circuit 105 selects the set of access settings 103n according to the output selection signal Sout transmitted from the control circuit 102;

Step S306: The data access circuit 106 performs a low-speed write operation on the NAND memory die 12n according to the output driver strength corresponding to the set of access settings 103n;

Step S308: The data access circuit 106 performs a high-speed read operation on the NAND memory die 12n according to the on-die termination corresponding to the set of access settings 103n;

Step S310: The central control unit 100 determines whether the on-die termination corresponding to the set of access settings 103n is usable? If so, exit the method 300; and if not, proceed to Step S312;

Step S312: The input selection circuit 101 outputs another on-die termination setting to the first internal memory 103 according to the input selection signal Sin from the control circuit 102 to update the on-die termination of the set of access settings 103n corresponding to the NAND memory die 12n; proceed to Step S304.

Steps S302 and S304 are identical to Steps S202 and S204, explanation therefor will be omitted for brevity. To obtain an on-die termination corresponding to the NAND memory die 12n, the data access circuit 106 writes predetermined data into the NAND memory die 12n at a low writing speed (Step S306), and then reads data from the NAND memory die 12n at a high reading speed (Step S308). In some embodiments, the low writing speed may be, but is not limited to, 50 MHz, and the high reading speed may be, but is not limited to, 1600 MHz. In Step S310, the central control unit 100 compares the read data to the predetermined data. If the read data matches the predetermined data, the central control unit 100 determines that the on-die termination corresponding to the NAND memory die 12n is usable, and the method 200 is exited. If the read data fails to match the predetermined data, the central control unit 100 determines that the on-die termination corresponding to the NAND memory die 12n is unusable. In Step S312, since the on-die termination is unusable, the central control unit 100 outputs another on-die termination setting to update the on-die termination corresponding to the set of access settings 103n. In some embodiments, said another on-die termination setting corresponds to another on-die termination resistance less than the previous on-die termination resistance of the on-die termination. Steps S304-S312 are repeated until a usable on-die termination is acquired.

The memory controller 10 executes the control method 300 on the NAND memory dies 121-12N in turn to obtain the on-die terminations corresponding to the plurality of sets of access settings 1031-103N. While in the embodiment, the method 300 may be exited upon obtaining the usable on-die termination, in other embodiments, the memory controller 10 may execute the method 300 to iterate over all on-die termination settings and determine all usable on-die termination resistances, and update the maximum on-die termination resistance among all the usable on-die termination resistances as the on-die termination corresponding to the set of access settings 103n, so as to reduce power consumption while reading data from the NAND memory die 12n accurately.

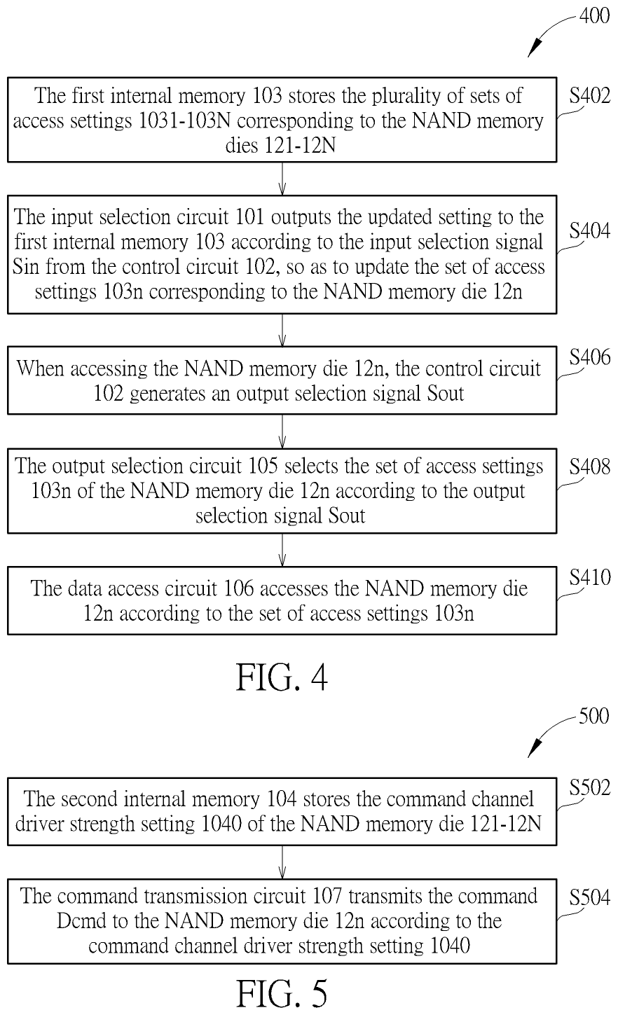

FIG. 4 is a flowchart of another method 400 of controlling the memory controller 10. The control method 400 includes steps S402-S410 for use to access a selected NAND memory die 12n. Any reasonable step change or adjustment is within the scope of the disclosure. Steps S402-S410 are detailed as follows:

Step S402: The first internal memory 103 stores the plurality of sets of access settings 1031-103N corresponding to the NAND memory dies 121-12N;

Step S404: The input selection circuit 101 outputs the updated setting to the first internal memory 103 according to the input selection signal Sin from the control circuit 102, so as to update the set of access settings 103n corresponding to the NAND memory die 12n;

Step S406: When accessing the NAND memory die 12n, the control circuit 102 generates an output selection signal Sout;

Step S408: The output selection circuit 105 selects the set of access settings 103n of the NAND memory die 12n according to the output selection signal Sout;

Step S410: The data access circuit 106 accesses the NAND memory die 12n according to the set of access settings 103n.

In Step S404, the central control unit 100 outputs the usable driver strength setting and/or the usable on-die termination setting as the update setting to update the set access setting 103n. In some embodiments, the usable driver strength setting may correspond to the maximum usable driver resistance, and the usable on-die termination setting may correspond to the maximum usable on-die termination resistance.

For example, when the usable driver resistances of the NAND memory die 12n are 25 ohms and 35 ohms, and the usable on-die termination resistances are 50 ohms and 75 ohms, the central control unit 100 may output the usable driver strength settings corresponding to 35 ohms and the on-die termination setting corresponding to 75 ohms to serve as the updated setting. In other embodiments, the usable driver strength setting may correspond to an arbitrary selection from the usable driver resistances, and the usable on-die termination setting may correspond to an arbitrary selection from the usable on-die termination resistances. The explanation for Steps S402, S406-S410 has been provided in the preceding paragraphs, and will be omitted here for brevity.

The control method 400 may perform data access according to a set of corresponding access settings of each NAND memory die, so as to enhance the performance of the memory device 1 and reduce the power consumption of the memory device 1.

FIG. 5 is a flowchart of another method 500 of controlling the memory controller 10. The control method 500 includes steps S502 and S504 for use to transmit the command Dcmd to the selected NAND memory die 12n. Any reasonable step change or adjustment is within the scope of the disclosure. Steps S502 and S504 are detailed as follows:

Step S502: The second internal memory 104 stores the command channel driver strength setting 1040 of the NAND memory die 121-12N;

Step S504: The command transmission circuit 107 transmits the command Dcmd to the NAND memory die 12n according to the command channel driver strength setting 1040.

The explanation for Steps S502 and S504 has been provided in the preceding paragraphs, and will be omitted here for brevity. Since the transmission speed of the command Dcmd is low, the control method 500 may use the same command channel driver setting 1040 to transmit the command Dcmd to the NAND memory die 121-12N, thereby reducing the manufacturing cost without degrading the transmission performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory controller capable of accessing a plurality of NAND memory dies, and the memory controller comprising:
a first internal memory configured to store a plurality of sets of access settings corresponding to the plurality of NAND memory dies;
an output selection circuit coupled to the first internal memory and configured to select a set of access settings corresponding to a NAND memory die according to an output selection signal;
a control circuit coupled to the output selection circuit and configured to generate the output selection signal when accessing the NAND memory die; and
a data access circuit coupled to the output selection circuit and configured to access the NAND memory die according to the set of access settings.

2. The memory controller of claim 1, wherein the set of access settings comprises an output driver strength and an on-die termination.

3. The memory controller of claim 2, wherein the data access circuit transmits data to the NAND memory die according to the output driver strength.

4. The memory controller of claim 2, wherein the data access circuit receives data from the NAND memory die according to the on-die termination.

5. The memory controller of claim 1, further comprising:
a central control unit configured to output a set of updated settings; and
an input selection circuit coupled to the central control unit, the first internal memory and the control circuit, and configured to output the set of updated settings to the first internal memory according to an input selection signal from the control circuit, so as to update the set of access settings corresponding to the NAND memory die.

6. The memory controller of claim 5, further comprising:
a second internal memory coupled to the central control unit and configured to store a command channel driver setting of the plurality of NAND memory dies; and
a command transmission circuit coupled to the second internal memory and configured to transmit a command to the NAND memory die according to the command channel driver setting.

7. The memory controller of claim 1, wherein the control circuit generates the output selection signal according to a chip enable signal corresponding to the NAND memory die.

8. The memory controller of claim 1, wherein the control circuit generates the output selection signal according to a logical unit number corresponding to the NAND memory die.

9. The memory controller of claim 1, wherein the control circuit generates the output selection signal according to a volume corresponding to the NAND memory die.

10. A method of controlling a memory controller, the memory controller being coupled to a plurality of NAND memory dies, the memory controller comprising a first internal memory, an output selection circuit, a control circuit and a data access circuit, the output selection circuit being coupled to the first internal memory, the control circuit and the data access circuit being coupled to the output selection circuit, and the method comprising:
storing, by the first internal memory, a plurality of sets of access settings corresponding to the plurality of NAND memory dies;
generating, by the control circuit, an output selection signal when accessing a NAND memory die;
selecting, by the output selection circuit, a set of access settings corresponding to the NAND memory die according to the output selection signal; and
accessing, by the data access circuit, the NAND memory die according to the set of access settings.

11. The method of claim 10, wherein the set of access settings comprises an output driver strength and an on-die termination.

12. The method of claim 11, wherein the data access circuit accessing the NAND memory die according to the set of access settings comprises: the data access circuit transmitting data to the NAND memory die according to the output driver strength.

13. The method of claim 11, wherein the data access circuit accessing the NAND memory die according to the set of access settings comprises: the data access circuit receiving data from the NAND memory die according to the on-die termination.

14. The method of claim 10, wherein the memory controller further comprises a central control unit and an input selection circuit, the input selection circuit is coupled to the central control unit, the first internal memory and the control circuit, and the method further comprises:
outputting, by the input selection circuit, the set of updated settings to the first internal memory according to an input selection signal from the control circuit, so as to update the set of access settings corresponding to the NAND memory die.

15. The method of claim 14, wherein the memory controller further comprises a second internal memory and a command transmission circuit, the second internal memory is coupled to the central control unit, the command transmission circuit is coupled to the second internal memory, and the method further comprises:
storing, by the second internal memory, a command channel driver setting of the plurality of NAND memory dies; and
transmitting, by the command transmission circuit, a command to the NAND memory die according to the command channel driver setting.

16. The method of claim 10, wherein the control circuit generating the output selection signal comprises:
the control circuit generating the output selection signal according to a chip enable signal corresponding to the NAND memory die.

17. The method of claim 10, wherein the control circuit generating the output selection signal comprises:
the control circuit generating the output selection signal according to a logic unit number corresponding to the NAND memory die.

18. The method of claim 10, wherein the control circuit generating the output selection signal comprises:
the control circuit generating the output selection signal according to a volume corresponding to the NAND memory die.
